(19) United States
(12) Patent Application Publication
(10) Pub. No.: US 2022/0270873 A1
(43) Pub. Date: Aug. 25, 2022

(54) METHOD FOR PROCESSING SEMICONDUCTOR DEVICE

(71) Applicant: CHANGXIN MEMORY TECHNOLOGIES, INC., Hefei City (CN)

(72) Inventor: Jian ZHANG, Hefei City (CN)

(73) Assignee: CHANGXIN MEMORY TECHNOLOGIES, INC., Hefei City (CN)

(21) Appl. No.: 17/650,511

(22) Filed: Feb. 9, 2022

Related U.S. Application Data
(63) Continuation of application No. PCT/CN2021/111308, filed on Aug. 6, 2021.

(30) Foreign Application Priority Data
Jan. 18, 2021 (CN) 202110061590.9

(51) Int. Cl. H01L 21/02; H01L 21/321; C23C 16/455; C23C 16/458

(52) U.S. Cl. CPC H01L 21/02274; H01L 21/3212; C23C 16/45536; C23C 16/4584

(57) ABSTRACT

A method for processing a semiconductor device includes that: the semiconductor device is provided, the semiconductor device having a surface to be etched and a non-etched surface opposite to the surface to be etched; a protective layer is formed on the non-etched surface; the semiconductor device is placed on a bearing device with the surface to be etched facing upward and an edge of the semiconductor device being clamped between a plurality of pins; the bearing device is rotated, and an etching solution is sprayed onto the surface to be etched to etch the surface to be etched; and the protective layer is removed, the protective layer being insoluble in the etching solution.

### CROSS-REFERENCE TO RELATED APPLICATIONS

This is a continuation of International Application No. PCT/CN2021/111308 filed on Aug. 6, 2021, which claims priority to Chinese Patent Application No. 202110061590.9 filed on Jan. 18, 2021. The disclosures of the above-referenced applications are hereby incorporated by reference in their entirety.

### BACKGROUND

In a manufacturing process of a semiconductor device, a film layer with an appropriate thickness on the back surface of the semiconductor device is generally removed to overcome the problem of semiconductor structure defects caused by the stress generated by the thickness of the film layer.

### SUMMARY

The embodiments of the present disclosure relate to the field of semiconductor manufacturing technologies and provide a method for processing a semiconductor device processing. The method includes the following operations.

A semiconductor device is provided. The semiconductor device has a surface to be etched and a non-etched surface opposite to the surface to be etched.

A protective layer is formed on the non-etched surface.

The semiconductor device is placed on a bearing device with the surface to be etched facing upward and an edge of the semiconductor device being clamped between multiple pins.

The bearing device is rotated, and an etching solution is sprayed onto the surface to be etched to etch the surface to be etched.

The protective layer is removed. The protective layer is insoluble in the etching solution.

### BRIEF DESCRIPTION OF THE DRAWINGS

The above and other features and advantages of the present disclosure will become more apparent by describing the exemplary embodiments thereof in detail with reference to the accompanying drawings.

FIG. 1 is a flowchart of a method for processing a semiconductor device in an exemplary embodiment of the present disclosure.

FIG. 2 is a schematic structural view of an etching device in an exemplary embodiment of the present disclosure.

FIG. 3 is a partial schematic view of an etching device, showing a position relationship among a bearing device, pins and a semiconductor device, in an exemplary embodiment of the present disclosure.

FIG. 4 is a schematic top view of a bearing device in an etching device in an exemplary embodiment of the present disclosure.

FIG. 5 is a schematic view of a defect caused by an etching solution flowing to a non-etched surface in an exemplary embodiment of the present disclosure.

FIG. 6 is a schematic view of a defect obtained by performing a film control test on a non-etched surface.

FIG. 7 is a first schematic view of a final defect of a semiconductor device caused by an edge defect in an exemplary embodiment of the present disclosure.

FIG. 8 is a second schematic view of a final defect of a semiconductor device caused by an edge defect in an exemplary embodiment of the present disclosure.

FIG. 9 is a third schematic view of a final defect of a semiconductor device caused by an edge defect in an exemplary embodiment of the present disclosure.

FIG. 10 is a fourth schematic view of a final defect of a semiconductor device caused by an edge defect in an exemplary embodiment of the present disclosure.

FIG. 11 is a fifth schematic view of a final defect of a semiconductor device caused by an edge defect in an exemplary embodiment of the present disclosure.

FIG. 12 is a schematic top view of a defect of a semiconductor device in an exemplary embodiment of the present disclosure.

FIG. 13 is a schematic structural view of a semiconductor device in an exemplary embodiment of the present disclosure.

FIG. 14 is a schematic structural view of a semiconductor device after a protective layer is formed on a non-etched surface in an exemplary embodiment of the present disclosure.

FIG. 15 is a schematic structural view of a semiconductor device after an etching surface is etched in an exemplary embodiment of the present disclosure.

FIG. 16 is a schematic structural view of a semiconductor device after a protective layer is removed in an exemplary embodiment of the present disclosure.

FIG. 17 is a schematic structural view of a semiconductor device after an oxide layer is removed in an exemplary embodiment of the present disclosure.

### REFERENCE NUMERALS

1. semiconductor device; 11. functional structure; 12. substrate; 13. oxide layer; 14. surface to be etched; 15. non-etched surface; 16. protective layer; 2. etching device; 21. bearing device; 22. gas pipeline; 23. gas vent; 24. pin; 25. nozzle; 26. etching solution; D. edge defect; F. final defect.

### DETAILED DESCRIPTION

Exemplary embodiments will now be described more fully with reference to the accompanying drawings. However, the exemplary embodiments can be implemented in various forms, and should not be construed as being limited to the embodiments set forth herein. On the contrary, these embodiments are provided so that the present disclosure will be comprehensive and complete, and will fully convey the concept of the exemplary embodiments to those skilled in the art. The same reference numerals in the figures indicate the same or similar structures, and thus the detailed descriptions thereof are omitted.

In the following descriptions of different exemplary embodiments of the present disclosure, reference is made to the accompanying drawings, and the accompanying drawings form a part of the present disclosure, in which different exemplary structures that may implement various aspects of the present disclosure are shown by way of example. It should be understood that other specific solutions of components, structures, exemplary devices, systems and operations may be used, and structural and functional modifications may be made without departing from the scope of the present disclosure. Moreover, although the terms “above”, “between”, and “within” and the like may be used in the description to describe different exemplary features and elements of the present disclosure, these terms are used herein for convenience only, for example, according to the direction of an example in the figures. Any content in the description should not be understood as requiring a specific three-dimensional direction of the structure to fall within the scope of the present disclosure. In addition, the terms “first”, and “second” and the like in the claims are only used as marks, and are not numerical limitations on their objects.

Reference throughout this specification to “one embodiment,” “an embodiment,” “an example,” “some embodiments,” “some examples,” or similar language means that a particular feature, structure, or characteristic described is included in at least one embodiment or example. Features, structures, elements, or characteristics described in connection with one or some embodiments are also applicable to other embodiments, unless expressly specified otherwise.

In a manufacturing process of a semiconductor device, a film layer on the back surface (that is, the surface to be etched) of the semiconductor device is generally thicker and needs to be thinned Otherwise, the film layer is easy to accumulate stress, causing deformation of the semiconductor device. Furthermore, in the subsequent manufacturing process, the film layer may also be split or peeled off, causing defects in the semiconductor device, and also affecting the defocusing and alignment of a yellow light process. Therefore, in the manufacturing process of the semiconductor device, the film layer with an appropriate thickness on the back surface of the semiconductor device is generally removed to overcome the problem of semiconductor structure defects caused by the stress generated by the thickness of the film layer.

According to some exemplary embodiments, use of a wet etching technology to remove the film layer on the back surface of the semiconductor device. When the film layer on the back surface is etched by an etching device, the semiconductor device is generally placed on a bearing device with the film layer on the back surface facing upward and the edge of the semiconductor device being fixed by multiple pins. In the etching process, the bearing device rotates at a high speed, and an etching solution diffuses outward under the action of centrifugal force. When the etching solution diffuses to the edge of the film layer on the back surface, the etching solution will temporarily stay on the edge and then flow to the edge of the front surface of the semiconductor device along the gaps between the pins and the semiconductor device, so that the film layer on the edge of the front surface of the semiconductor device is partially damaged, causing a structural defect on the front surface of the semiconductor device. As a result, the film on the edge of the front surface of the semiconductor device is easily peeled off to the center of the semiconductor device, and the product yield is reduced.

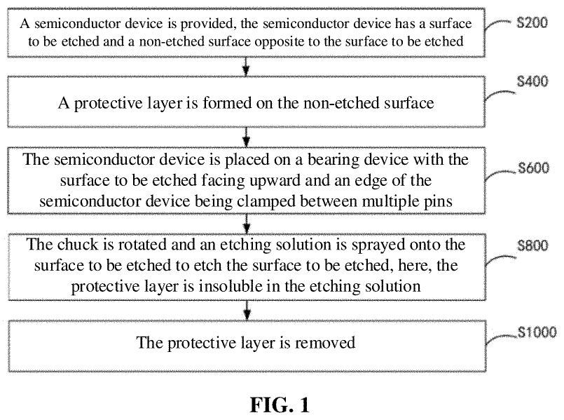

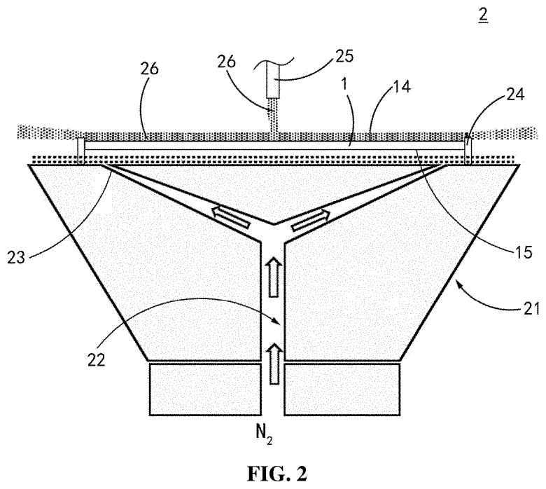

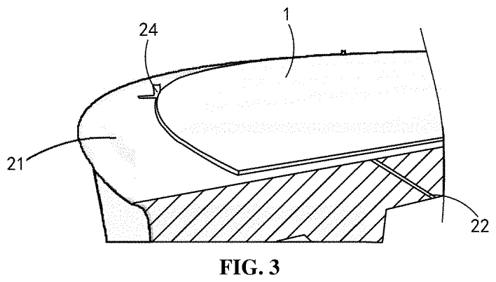

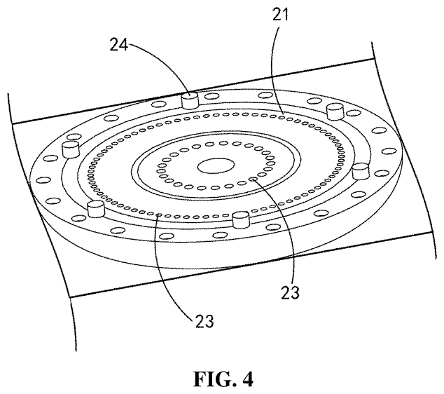

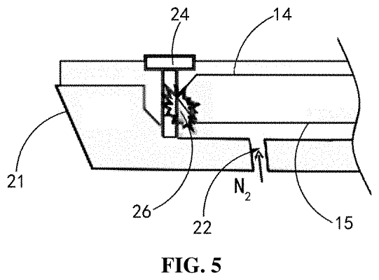

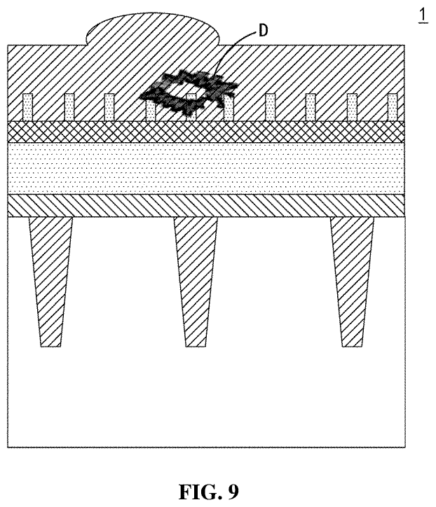

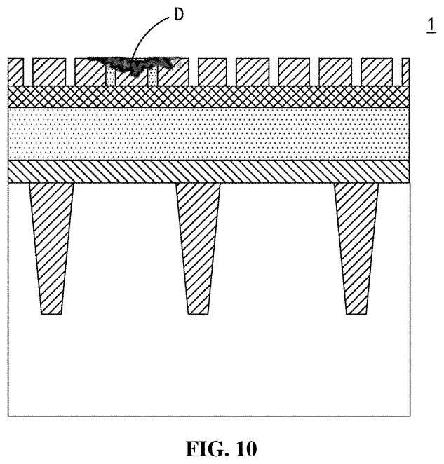

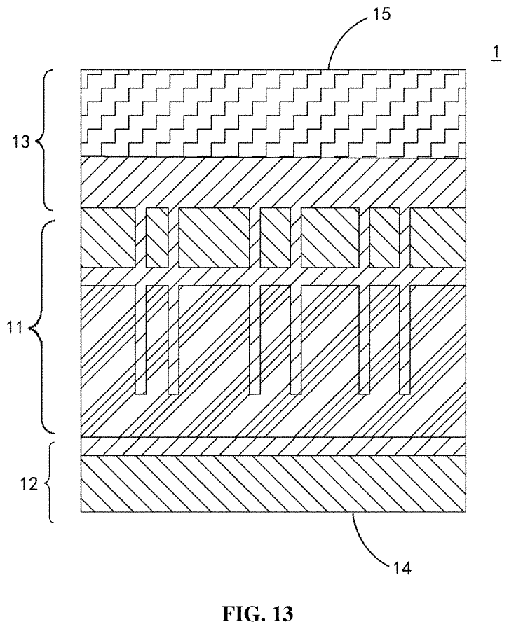

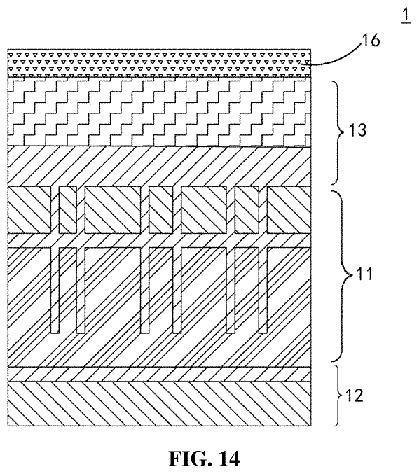

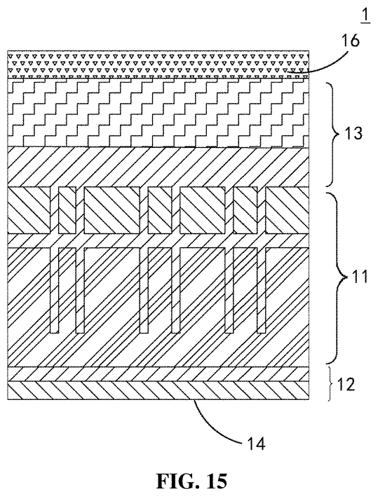

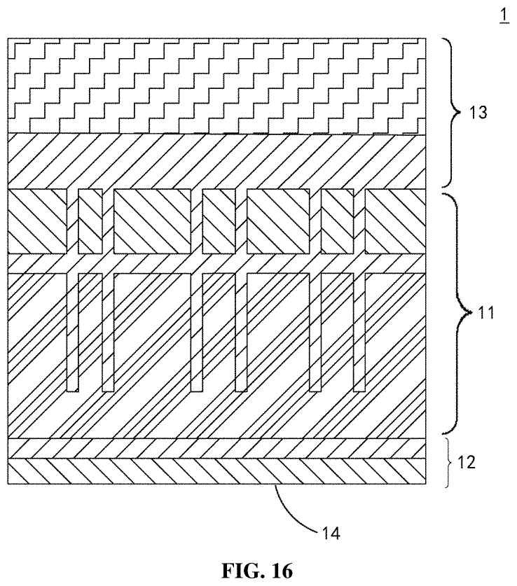

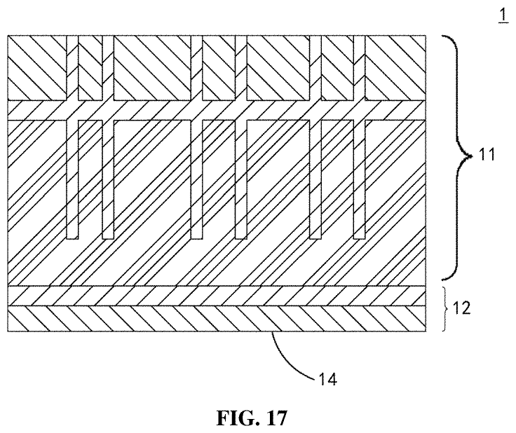

Referring to FIG. 1 to FIG. 17, FIG. 1 shows a flowchart of a method for processing a semiconductor device 1. FIG. 2 to FIG. 4 show schematic structural views of an etching device 2. FIG. 5 to FIG. 12 show schematic views of a structure of a semiconductor device 1 and a final defect F of the semiconductor device 1 due to an edge defect D on a non-etched surface 15. FIG. 13 to FIG. 17 show a processing method for forming a protective layer 16 on a non-etched surface 15 of the semiconductor device 1. As shown in FIG. 1, the method for processing the semiconductor device 1 of the present disclosure includes the following operations.

In operation S200, the semiconductor device 1 is provided, and the semiconductor device 1 has a surface 14 to be etched and a non-etched surface 15 opposite to the surface 14 to be etched.

In operation S400, a protective layer 16 is formed on the non-etched surface 15.

In operation S600, the semiconductor device 1 is placed on a bearing device 21 with the surface 14 to be etched facing upward and an edge of the semiconductor device 1 being clamped between multiple pins 24.

In operation S800, the bearing device 21 is rotated, and an etching solution 26 is sprayed onto the surface 14 to be etched to etch the surface 14 to be etched.

In operation S1000: the protective layer 16 is removed.

Herein, the protective layer 16 is insoluble in the etching solution 26.

In the method for processing the semiconductor device 1 of the present disclosure, before the surface 14 to be etched of the semiconductor device 1 is etched, the protective layer 16 is formed on the non-etched surface 15 and the protective layer 16 is insoluble in the etching solution 26. Therefore, in the etching process, the etching solution 26 cannot remove the protective layer 16, so as to effectively avoid the edge defect caused by the etching solution 26 flowing to the edge of the non-etched surface 15 of the semiconductor device 1, and further avoid a defect formed by peeling off of an edge film layer caused by the irregular edge of the non-etched surface 15. Furthermore, the method for processing the semiconductor device provided by the embodiments of the present disclosure has a simple process and saves the manpower and cost.

It should be noted that in operation S600, the surface 14 to be etched faces upward, which means that the surface 14 to be etched faces a nozzle 25. The term “upward” means orientation. For example, after the semiconductor device 1 is placed on the bearing device 21, the surface to be etched of the semiconductor device faces upward and the non-etched surface of the semiconductor device faces downward relative to the semiconductor device.

The method for processing the semiconductor device 1 of the present disclosure will be described in detail below.

In operation S200, the semiconductor device 1 is provided, and the semiconductor device 1 has a surface 14 to be etched and a non-etched surface 15 opposite to the surface 14 to be etched.

The semiconductor device 1 may be a wafer, which is not specifically limited here.

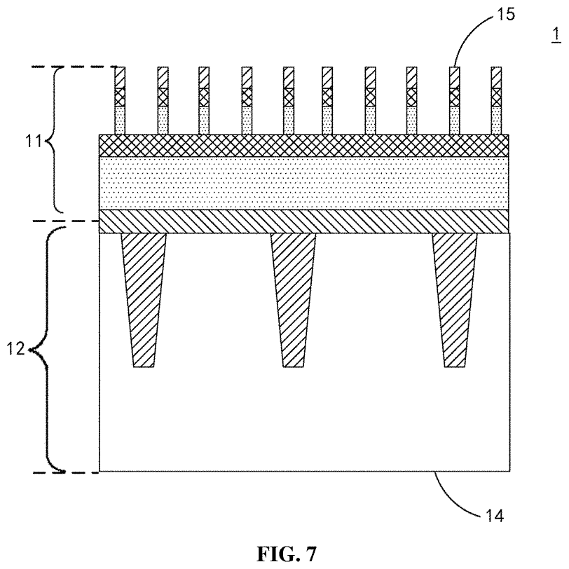

FIG. 7 shows a schematic cross-sectional structural view of a semiconductor device 1. The semiconductor device 1 generally includes a semiconductor base. Shallow trench isolation structures are formed on the semiconductor base, an active area is arranged between the shallow trench isolation structures, and a functional structure 11, such as a word line structure, is arranged in the active area. The word line structure may include a high-dielectric constant dielectric layer, a polysilicon layer, a work function layer, a word line metal layer, and the like. In addition, an oxide layer may be arranged on the functional structure 11 of the semiconductor base of the semiconductor device 1 to prevent the functional structure 11 of the semiconductor device 1 from being damaged.

Exemplarily, the base of the semiconductor device 1 provided by the embodiments of the present disclosure may include a substrate 12. The material of the substrate 12 may be silicon, silicon carbide, silicon nitride, silicon on insulator, stacked silicon on insulator, stacked silicon germanide on insulator, silicon germanide on insulator, germanium on insulator, or the like.

Exemplarily, the bottom surface of the base of the semiconductor device 1 can be understood as the surface 14 to be etched in the embodiments of the present disclosure, and the other surface opposite to the bottom surface of the base of the semiconductor device 1 can be understood as the non-etched surface 15 of the present disclosure. In the manufacturing process of the semiconductor device 1, it is generally necessary to thin the surface 14 to be etched of the base of the semiconductor device 1 to avoid the base from being too thick. Otherwise, in the subsequent manufacturing process, stress concentration occurs in the base of the semiconductor device 1, which causes deformation.

Generally, the surface 14 to be etched of the semiconductor device 1 is thinned by a wet etching technology. The wet etching generally uses a specific chemical etching solution 26 to remove, through a chemical reaction, the part of the surface of the semiconductor device 1 that needs to be etched.

FIG. 2 exemplarily shows a schematic structural view of an etching device 2. The wet etching device 2 includes a bearing device 21 for bearing the semiconductor device 1. The bearing device 21 has a chamber with an opening facing upward, and the semiconductor device 1 is arranged in the chamber. A gas pipeline 22 is arranged inside the bearing device 21, and nitrogen can be introduced into the gas pipeline 22. In addition, multiple gas vents 23 are provided at the upper part of the bearing device 21, and the gas vents 23 are connected with the gas pipeline 22. When nitrogen is introduced into the gas pipeline 22, the nitrogen is ejected from the gas vents 23 to sweep/purge the non-etched surface 15 of the semiconductor device 1, thereby preventing the etching solution 26 from flowing to the non-etched surface 15 so as to protect the non-etched surface 15.

The bearing device 21 can rotate at a high speed, so that the etching solution 26 can be quickly and evenly/uniformly distributed on the surface 14 to be etched. Multiple pins 24 are arranged on the bearing device 21, and the pins 24 are used for fixing the semiconductor device 1. As shown in FIG. 2 to FIG. 4, after the semiconductor device 1 is placed on the bearing device 21, the multiple pins 24 are distributed at the edge of the semiconductor device 1 to clamp the semiconductor device 1 on the bearing device 21 so as to prevent the semiconductor device 1 from being thrown out when the bearing device 21 rotates. Exemplarily, the bearing device 21 may be a chuck.

The number of the pins 24 may be 3, 4, 5, 6 or more, which may be set by those skilled in the art according to actual needs, and there is no special limitation here. In this embodiment, six pins 24 distributed annularly at equal intervals are arranged on the bearing device 21.

As shown in FIG. 2, the etching device 2 further includes a nozzle 25. The nozzle 25 is arranged above the bearing device 21, specifically, above the center of the semiconductor device 1. The nozzle 25 is configured to spray the etching solution 26 to the surface 14 to be etched of the semiconductor device 1.

In addition, the etching device 2 may also include a machine table and a robot (not shown in the figures). The robot is arranged on the machine table, and the robot can put the semiconductor device 1 into the chamber of the bearing device 21 by means of automatic control.

Specifically, as shown in FIG. 2, the method for processing the surface 14 to be etched of the semiconductor device 1 mainly includes that: the surface 14 to be etched of the semiconductor device 1 to be cleaned is turned upward, the semiconductor device 1 is placed on the bearing device 21 (chuck) with the chamber by using the robot on the machine table, and the edge of the semiconductor device 1 is clamped by multiple pins 24 on the bearing device 21. The nozzle 25 sprays the etching solution 26 to the surface 14 to be etched of the semiconductor device 1 to etch the surface 14 to be etched of the semiconductor device 1, so as to remove a film layer with an appropriate thickness on the surface 14 to be etched of the semiconductor device 1. At the same time, the nitrogen (N₂) in a nitrogen pipeline is blown to the downward non-etched surface 15 of the semiconductor device 1 through the gas vents 23 to purge the non-etched surface 15, so that the non-etched surface 15 of the semiconductor device 1 is protected to prevent the etching solution 26 from flowing to the middle part of the non-etched surface 15 of the semiconductor device 1.

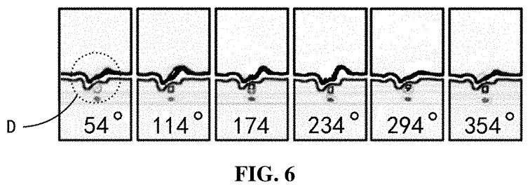

According to some exemplary embodiments, when the etching solution 26 is sprayed to the surface 14 to be etched of the semiconductor device 1, due to the high-speed rotation of the bearing device 21, the etching solution 26 diffuses outward under the action of centrifugal force. As shown in FIG. 5, when the etching solution diffuses to the edge of the semiconductor device 1, since the edge of the semiconductor device 1 is clamped between the multiple pins 24, the multiple pins 24 play a role in blocking the etching solution 26, and the etching solution 26 will temporarily stay on the edge of the semiconductor device 1 and flow along the pins 24 to the edge of the non-etched surface 15 of the semiconductor device 1. As a result, the film layer on the edge of the non-etched surface 15 of the semiconductor device 1 is partially damaged, forming an edge defect D, as shown in FIG. 6.

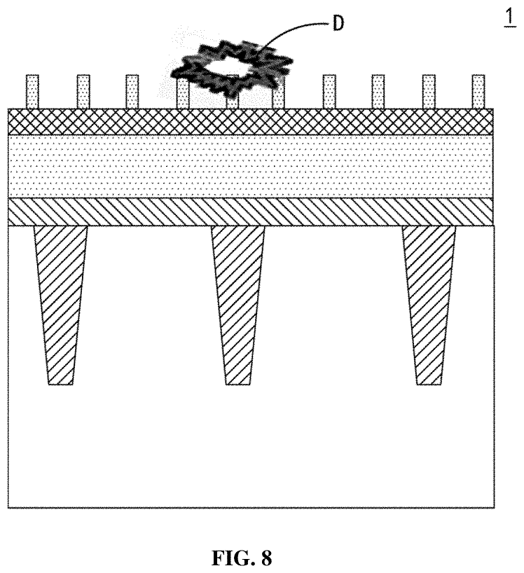

The edge defect D of the non-etched surface 15 of the semiconductor device 1 will form an irregular pattern, which may affect the subsequent processes of the semiconductor device 1. Specifically, the etching solution 26 causes the irregular edge of the non-etched surface 15 of the semiconductor device 1, which will affect the adhesion of the front surface of the semiconductor device 1 in the subsequent film growth process, as shown in FIG. 8 to FIG. 10, so that the film on the edge of the non-etched surface 15 of the semiconductor device 1 easily peels off to the center of the semiconductor device 1. For example, when the semiconductor device 1 is cleaned in an acid bath, the irregular film on the edge of the semiconductor device 1 may peel off from the edge to the center, thereby forming an edge defect D with a bevel. In the embodiments of the present disclosure, the non-etched surface 15 is an SiN film. It is found through the film control test of the SiN film that when the surface 14 to be etched is etched, if the etching solution 26 (such as a hydrofluoric acid solution) can dissolve the non-etched surface 15, the edge of the non-etched surface 15 will be damaged. FIG. 6 shows the edge defects D formed by the non-etched surface 15 at the six pins 24 in this embodiment. It can be seen from the figure that the edge defect D is a depression formed inward. For the edge defects D generated on the edge parts of the non-etched surface 15 at the six pins 24 in the figure, 54° to 354° represent the corresponding angle positions of each of the six pins 24 on the bearing device 21. When a liquid that cannot dissolve SiN is used, it can be known according to the film control test of the SiN film that the edge of the non-etched surface 15 does not have the above defect.

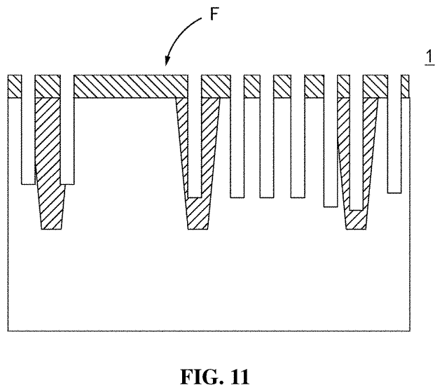

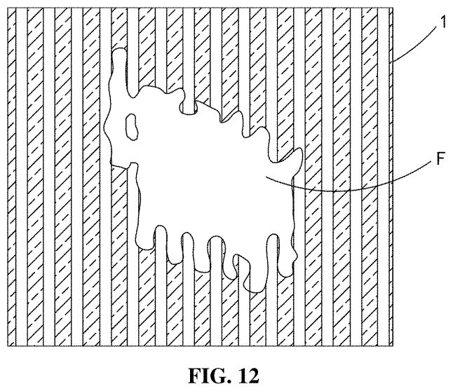

Continuing to refer to FIG. 8 to FIG. 12, the edge defect D always exists on the non-etched surface 15 of the semiconductor device 1, which affects the formation of other functional structures 11 of the semiconductor device 1 in the subsequent processes of the semiconductor device 1. As shown in FIG. 11 to FIG. 12, the edge defect D causes uneven etching of the base of the semiconductor device 1, resulting in a final defect F of the semiconductor device 1, so that the yield of the semiconductor device 1 is reduced.

However, since the pins 24 on the bearing device 21 are fixed, the edge damage cannot be completely removed by simply optimizing the formulation of the etching solution 26 or the formulation of the film layer. At present, the edge defect D of the semiconductor device 1 cannot be effectively reduced.

In order to solve the above problems, FIG. 1 and FIG. 13 to FIG. 17 respectively show a flowchart of a manufacturing method of the semiconductor device 1 of the present disclosure and schematic structural views of the semiconductor device 1 in various operations. The manufacturing method in the embodiments of the present disclosure may include that: in operation S400, a protective layer 16 is formed on the non-etched surface 15.

That is, before the semiconductor device 1 is subjected to wet etching, the protective layer 16 is formed on the non-etched surface 15. The protective layer 16 is insoluble in the etching solution 26.

Exemplarily, in the embodiments of the present disclosure, the etching solution 26 may be a hydrofluoric acid solution with a mass fraction of 40% to 49%, such as 42%, 45% or 48%, which is not specifically limited here. In this embodiment, the concentration of the hydrofluoric acid solution is 49%.

Exemplarily, in the embodiments of the present disclosure, the protective layer 16 may be a film layer formed by polysilicon or amorphous silicon. The polysilicon and amorphous silicon are insoluble in the hydrofluoric acid solution, so that when the surface 14 to be etched of the semiconductor device 1 is etched, even if the etching solution 26 partially flows to the edge of the non-etched surface 15, the protective layer 16 cannot be damaged to avoid the damage to the non-etched surface 15 under the protective layer 16, and further avoid the defect formed by peeling off of the edge film layer caused by the irregular edge of the non-etched surface 15. It can also be concluded through the film control test that the non-etched surface 15 with the protective layer 16 thereon is not damaged by the etching solution to form an edge defect.

Specifically, the protective layer 16 can be formed on the non-etched surface 15 of the semiconductor device 1 by Plasma Enhanced Chemical Vapor Deposition (PECVD), so that an even/uniform protective layer 16 with a controllable thickness can be formed. In this embodiment, the thickness of the protective layer 16 may be 5 nm to 15 nm, such as 8 nm, 10 nm, 12 nm or 13 nm. Of course, the protective layer 16 may also have other thicknesses. Those skilled in the art can adjust the thickness according to the specific size of the semiconductor device 1. There is no special limitation here.

Exemplarily, in the method for processing the semiconductor device 1 of the present disclosure, an oxide layer 13 may be formed on the non-etched surface 15 of the semiconductor device 1, and then a protective layer 16 is formed on the oxide layer 13. The oxide layer 13 may be silicon oxide. The oxide layer 13 can protect the semiconductor device 1 during the processing of the semiconductor device 1. For example, the oxide layer 13 can protect word line structures, thin film transistors, conductive interconnection structures or other functional structures 11 in the semiconductor device 1. After the surface to be etched of the semiconductor device 1 is etched, the oxide layer 13 is removed.

The thickness of the oxide layer 13 may be 400 nm to 800 nm. In this embodiment, the thickness of the oxide layer 13 is 600 nm.

Referring to FIG. 1, after the protective layer 16 is formed, the operation S600 may be performed, which includes that: the semiconductor device 1 is placed on the bearing device 21 with the surface 14 to be etched facing upward and an edge of the semiconductor device 1 being clamped between multiple pins 24.

Specifically, the semiconductor device 1 is placed on the bearing device 21 by using a robot on a machine table, the surface 14 to be etched faces upward, and the semiconductor device 1 is fixed by the multiple pins 24.

Referring to FIG. 1, in operation S800, the bearing device 21 is rotated, and an etching solution 26 is sprayed onto the surface 14 to be etched to etch the surface 14 to be etched.

Specifically, a rotating shaft is arranged inside the bearing device 21, and the rotation speed of the rotating shaft may be controlled by a motor. After the bearing device 21 is rotated, the nozzle 25 located above the center of the semiconductor device 1 is opened, and the etching solution 26 is sprayed onto the surface 14 to be etched. Due to the high-speed rotation of the bearing device 21, by virtue of the centrifugal force, the etching solution 26 sprayed to the center of the surface 14 to be etched can be quickly and uniformly distributed to the entire surface 14 to be etched. The rotation speed of the bearing device 21 may be 1000 rpm to 1700 rpm, such as 1000 rpm, 1500 rpm or 1700 rpm.

The surface 14 to be etched can be dissolved in the etching solution 26 to realize the thinning of the surface 14 to be etched. In this embodiment, the material of the surface 14 to be etched of the semiconductor device 1 may be SiN (silicon nitride), of course, may also be other materials of the semiconductor substrate 12, such as SiC (silicon carbide). The material of the semiconductor substrate 12 needs to be selected according to the actual needs of the semiconductor device 1, and there is no special limitation here. In the method for processing the semiconductor device of the present disclosure, it is only necessary to ensure that the surface 14 to be etched can be dissolved in the etching solution 26.

At the same time, the gas pipeline 22 needs to be opened to blow nitrogen to the non-etched surface 15 through the gas vents 23, so that the non-etched surface 15 (which can be understood as the surface of the protective layer 16) is in a positive air pressure state relative to the surface 14 to be etched, so as to prevent the etching solution 26 from flowing to the non-etched surface 15. Of course, in addition to nitrogen, argon or other inert gases may also be used, and there is no special limitation here.

Then, the operation S1000 may be performed to remove the protective layer 16.

After the etching of the surface 14 to be etched is finished, the semiconductor device 1 is cleaned, and the robot is used for taking out the semiconductor device 1 or turning the semiconductor device 1 over to enable the non-etched surface 15 with the protective layer 16 thereon to face upward, so as to facilitate the removal of the protective layer 16.

Exemplarily, the protective layer 16 is etched by a plasma process. The etching gas used in the plasma process may be chlorine to remove the protective layer 16 made of amorphous silicon or polysilicon. By using chlorine for etching, the etching rate can reach 400 nm/min, which takes a short time and saves the time. The chlorine can etch the protective layer 16 and the oxide layer 13. Since the protective layer 16 is located on the oxide layer, the chlorine etches the protective layer 16 at first. When the protective layer 16 is etched down until reaching the point of contact with the oxide layer 13, the selection ratio of the chlorine to the protective layer 16 and the oxide layer 13 is about 5:1. In other words, the chlorine preferentially etches the protective layer 16 and hardly etches the oxide layer 13. In this embodiment, the thickness of the protective layer 16 is 10 nm. After the protective layer 16 is etched, the oxide layer 13 under the protective layer is hardly removed, thereby preventing the oxide layer 13 from being damaged and thus damaging the functional structure 11 of the semiconductor device 1.

Of course, if the thickness of the protective layer 16 is relatively thin, when the protective layer 16 is etched, a small part of the oxide layer 13 may be removed. However, the reduction of the oxide layer 13 will not affect the protection of the semiconductor device 1.

In another embodiment, the etching gas used in the plasma process may be a mixed gas of chlorine and oxygen to etch the protective layer 16. The volume ratio of oxygen to chlorine is 0 to 1:10, that is, the volume of chlorine is more than 10 times the volume of oxygen. It can be understood that when chlorine is introduced into the protective layer 16 for etching, an appropriate amount of oxygen may be introduced at the same time. The mixed gas of chlorine and oxygen can increase the selection ratio to the protective layer 16 and the oxide layer 13. For example, the selection ratio may reach 5:1 to 30:1. Therefore, even if the thickness of the protective layer 16 becomes thinner, the oxide layer 13 may not be damaged during etching with chlorine and oxygen.

After the protective layer 16 is removed, the oxide layer 13 is exposed on the non-etched surface 15 of the semiconductor device 1. At this time, the oxide layer 13 needs to be removed. Exemplarily, the oxide layer 13 may be removed by a chemical mechanical polishing technology, so as to make the surface of the semiconductor device 1 smoother and flatter.

In conclusion, in the method for processing the semiconductor device 1 of the present disclosure, before the surface 14 to be etched of the semiconductor device 1 is etched, the protective layer 16 is formed on the non-etched surface 15 and the protective layer 16 is insoluble in the etching solution 26, therefore, in the etching process, the etching solution 26 cannot remove the protective layer 16, so as to effectively prevent the edge damage caused by the etching solution 26 flowing to the edge of the non-etched surface 15 of the semiconductor device 1, and further prevent a defect formed by peeling off of an edge film layer caused by the irregular edge of the non-etched surface 15, thereby ensuring the structural integrity of the non-etched surface, and improving the product yield. Furthermore, the method for processing the semiconductor device provided by the embodiments of the present disclosure has a simple process and saves the manpower and cost.

It should be understood that the present disclosure does not limit its applications to the detailed structure and arrangement mode of components proposed in this specification. The present disclosure may have other embodiments, and may be implemented and executed in various ways. The deformations and modifications of the foregoing embodiments fall within the scope of the present disclosure. It should be understood that the present disclosure disclosed and defined in this specification extends to all alternative combinations of two or more individual features mentioned or obvious in the text and/or drawings. All these different combinations constitute multiple alternative aspects of the present disclosure. The embodiments described in this specification illustrate the best way known for implementing the present disclosure, and will enable those skilled in the art to utilize the present disclosure. The scope of the present disclosure is limited only by the appended claims.

What is claimed is:

1. A method for processing a semiconductor device, comprising:
providing the semiconductor device, the semiconductor device having a surface to be etched and a non-etched surface opposite to the surface to be etched;
forming a protective layer on the non-etched surface;
placing the semiconductor device on a bearing device with the surface to be etched facing upward and an edge of the semiconductor device being clamped between a plurality of pins;
rotating the bearing device, and spraying an etching solution onto the surface to be etched to etch the surface to be etched; and
removing the protective layer,
wherein the protective layer is insoluble in the etching solution.

2. The method of claim 1, wherein the protective layer is a polysilicon film.

3. The method of claim 1, wherein the protective layer is an amorphous silicon film.

4. The method of claim 1, wherein the protective layer has a thickness of 5 nm to 15 nm.

5. The method of claim 4, wherein the thickness of the protective layer is 10 nm.

6. The method of claim 1, wherein the protective layer is formed by plasma enhanced chemical vapor deposition.

7. The method of claim 1, wherein removing the protective layer comprises: performing etching by a plasma process.

8. The method of claim 7, wherein an etching gas used in the plasma process is chlorine.

9. The method of claim 7, wherein an etching gas used in the plasma process is a mixed gas of chlorine and oxygen.

10. The method of claim 9, wherein a volume ratio of the oxygen to the chlorine is 0 to 1:10.

11. The method of claim 1, wherein the etching solution is a hydrofluoric acid solution with a mass fraction of 40% to 49%.

12. The method of claim 1, further comprising: before forming the protective layer on the non-etched surface of the semiconductor device, forming an oxide layer on the non-etched surface of the semiconductor device.

13. The method of claim 12, wherein the oxide layer is a silicon oxide layer.

14. The method of claim 12, wherein the oxide layer has a thickness of 400 nm to 800 nm.

15. The method of claim 12, further comprising: after removing the protective layer, removing the oxide layer by chemical mechanical polishing.

16. The method of claim 1, wherein a material of the surface to be etched is SiN or SiC.

17. The method of claim 1, wherein the bearing device is a chuck.
